(19) United States
(12) Patent Application Publication
(10) Pub. No.: US 2023/0017238 A1
(43) Pub. Date: Jan. 19, 2023

(54) COMPOSITION FOR PHOTORESIST STRIPPER

(71) Applicant: ENF TECHNOLOGY CO., LTD., Gyeonggi-do (KR)

(72) Inventors: Hye Ji KIM, Gyeonggi-do (KR); Jin Ho YOU, Gyeonggi-do (KR); Namgi CHO, Gyeonggi-do (KR)

(21) Appl. No.: 17/844,107

(22) Filed: Jun. 20, 2022

(30) Foreign Application Priority Data
Jun. 28, 2021 (KR) 10-2021-0083719

(51) Int. Cl. C09K 13/00; C09K 15/30; G03F 7/42

(52) U.S. Cl. CPC C09K 13/00; C09K 15/30; G03F 7/425

(57) ABSTRACT

The present invention relates to a stripper composition for removing a photoresist in a process of manufacturing a semiconductor device.

According to the present invention, it is possible to prevent corrosion of the underlying film while improving the peeling force for the photoresist, and to improve the stability of the composition over time.

### TECHNICAL FIELD

The present invention relates to a stripper composition for removing a photoresist in a process of manufacturing a semiconductor device.

### BACKGROUND ART

The present invention relates to a stripper composition used for removing a photoresist in a process of manufacturing a semiconductor device and a method using the same. More specifically, it relates to a stripper composition for a negative photoresist, and to a stripper composition for a negative photoresist suitable for lithography processes such as wiring and bump formation when manufacturing a circuit board and installing semiconductors or electronic components on a circuit board.

Conventionally, an alkaline stripper has been used as a composition for removing a negative photoresist. As the alkaline stripper, a stripper composition composed of a water-soluble organic amine and an organic solvent are used. However, such an alkaline stripper has a problem that it does not have sufficient negative photoresist stripping ability and it is corrosive to metal.

In addition, when the tetramethylammonium hydroxide (TMAH) stripper used as a conventional photoresist stripper is fused with carbon dioxide by contacting with air, hydroxide ions constituting the alkali stripper are consumed to form hydrogen carbonates or carbonates (hereinafter also referred to as carbonate salts). A component of the alkaline stripper, in which the hydroxide ion is a counterion to the tetramethyl ammonium cation, has a stripping activity in free state in the stripper (i.e., in the form of hydroxide). Therefore, the stripping activity is reduced by the generation of carbonate salts due to fusion with carbon dioxide gas.

In order to solve these problems, a significant level of stripping properties is required for the removal ability of the photoresist and the anti-corrosion ability to the metal wiring, and also properties capable of reducing the denaturation of the alkaline stripper is required.

### DETAILED DESCRIPTION OF THE INVENTION

### Technical Problem

It is an object of the present invention to provide a stripper composition that prevents corrosion of metal while improving the stripping ability for the photoresist and improves the stability of the stripper.

### Solution to Problem

In order to solve the above problems, the present invention provides a composition for photoresist stripper comprising:

an organic solvent;

tetramethyl ammonium hydroxide;

an amine compound; and

an antioxidant,

wherein the composition does not contain an inorganic salt, and

wherein the antioxidant includes a compound of formula 1 or 2.

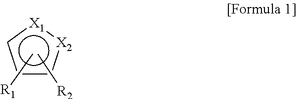

wherein

X₁ and X₂ are each independently N or O,

R₁ and R₂ are each independently H, a C₁₋₂ alkyl group, OH or NH₂, and are not H at the same time, and

when R₁ or R₂ is OH, X₁ or X₂ is O.

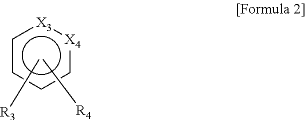

wherein

X₃ and X₄ are each independently N or O, and

R₃ and R₄ are each independently H, a C₁₋₂ alkyl group, COORₐ, OH or NH₂ and Rₐ is H or a C₁₋₂ alkyl group.

According to one embodiment, the antioxidant may include a compound of formula 1 or 2.

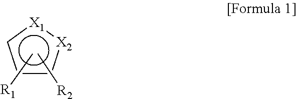

wherein

X₁ and X₂ are each independently N or O,

R₁ and R₂ are each independently H, a C₁₋₂ alkyl group, OH or NH₂, and are not H at the same time,

when R₁ or R₂ is OH, X₁ or X₂ is O, and

when R₁ or R₂ is a C₂ alkyl group, the other R¹ or R₂ is H.

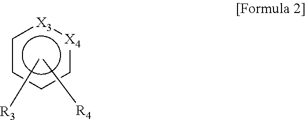

wherein

X₃ and X₄ are N, and

R₃ and R₄ are each independently H, a C₁₋₂ alkyl group, COOH or COOCH₃.

Specifically, for example, the antioxidant comprises one or more selected from 3-methyl pyrazole, 4-methyl pyridazine, 4,5-dimethyl pyridazine, 4-methyl isoxazole, 4-methyl-5-isoxazole, 4-methyl-5-isoxazolamine, 4-ethyl pyridazine, 4-ethyl-5-methyl pyridazine, 5-methyl-4-pyridazine amine, 4,5-dimethyl isoxazole, methyl pyridazine-4-carboxylate, 4-methyl pyrazole, 4-ethyl isoxazole, 3,4-dimethyl isoxazole and 4-methyl-5-isooxazolol.

According to one embodiment, the organic solvent may comprise one or more selected from dimethyl sulfoxide, ethyl pyrrolidone, methyl pyrrolidone, methyl formamide, ethyl formamide, diethyl formamide, dimethyl formamide, dimethyl acetamide, dipropylene glycol monomethyl ether, diethyl sulfoxide, dipropyl sulfoxide, sulfolane, pyrrolidone, dimethyl propionamide, and methyl propionamide

According to one embodiment, the amine compound may have a molecular weight of 80 to 250 g/mol.

Specifically, for example, the amine compound may comprise one or more selected from tetraethylene pentamine, amino ethoxy ethanol, mono ethanol amine, mono isopropanol amine, diethylene triamine, diisopropyl amine, and amino ethyl ethanol amine

According to other embodiment of the present invention, there is provided a method for producing a composition for photoresist stripper, comprising adding:

60 to 90% by weight of an organic solvent;

0.1 to 10% by weight of tetramethyl ammonium hydroxide;

0.1 to 10% by weight of an amine compound;

0.1 to 10% by weight of an antioxidant; and

the remaining amount of water so that the total weight of the composition is 100% by weight,

wherein no inorganic salt is added; and

wherein the antioxidant includes a compound of formula 1 or 2.

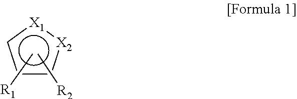

wherein

X₁ and X₂ are each independently N or O,

R₁ and R₂ are each independently H, a C₁₋₂ alkyl group, OH or NH₂, and are not H at the same time, and

when R₁ or R₂ is OH, X₁ or X₂ is O.

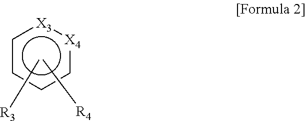

wherein

X₃ and X₄ are each independently N or O, and

R₃ and R₄ are each independently H, a C₁₋₂ alkyl group, COORₐ, OH or NH₂ and Rₐ is H or a C₁₋₂ alkyl group.

The specific details of other embodiments according to the present invention are included in the detailed description below.

### Effect of the Invention

According to the composition for photoresist stripper and the method for producing the same according to the present invention, it is possible to prevent corrosion of the underlying film while improving the stripping ability for the photoresist, and to improve the stability of the composition over time.

### BRIEF DESCRIPTION OF DRAWINGS

FIG. 1 shows photomicrographs of observing the degree of damage on the copper surface.

### MODE FOR CARRYING OUT THE INVENTION

The present invention may have various modification and various embodiments and specific embodiments will be illustrated in the drawings and described in detail. However, this is not intended to limit the present invention to specific embodiments, and should be understood to include all modifications, equivalents, and substitutes included in the spirit and scope of the present invention. In describing the present invention, if it is determined that a detailed description of a related known technology may obscure the gist of the present invention, the detailed description thereof will be omitted.

Unless otherwise specified, the expression “to” in relation to a number used herein is used as an expression including the corresponding numerical value. Specifically, for example, the expression “1 to 2” is meant to include all numbers between 1 and 2 as well as 1 and 2.

Hereinafter, a composition for photoresist stripper and a method for producing the same according to an embodiment of the present invention will be described in more detail.

The composition of the present invention removes the photoresist while preventing corrosion and damage to the underlying film by improving the density of the molecular layer of the antioxidant. In addition, the content change due to the decomposition of the alkali-based compound is minimized and the antioxidant effect of the antioxidant is improved, resulting in improving the stability of the composition over time.

Specifically, the present invention provides a composition for photoresist stripper comprising:

an organic solvent;

tetramethyl ammonium hydroxide;

an amine compound; and

an antioxidant,

wherein the composition does not contain an inorganic salt, and

wherein the antioxidant includes a compound of formula 1 or 2.

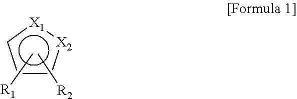

In the above formula, X₁ and X₂ are each independently N or O, for example, both may be N.

In addition, in the above formula, R₁ and R₂ are each independently H, a C₁₋₂ alkyl group, OH or NH₂, and are not H at the same time, for example, each independently H, a methyl group, an ethyl group, OH or NH₂,

when R₁ or R₂ is OH, X₁ or X₂ is O, which does not mean that when R₁ or R₂ is not OH, then X₁ or X₂ is not O.

In addition, in the above formula, when R₁ or R₂ is a C₂ alkyl group, the other R₁ or R₂ may be H.

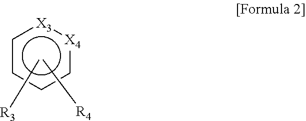

In the above formula,

X₃ and X₄ are each independently N or O, for example N, R₃ and R₄ are each independently H, a C₁₋₂ alkyl group, COORₐ, OH or NH₂ and Rₐ is H or a C₁₋₂ alkyl group, for example each independently H, a C₁₋₂ alkyl group, COOH, or COOCH₃.

Specifically, for example, the antioxidant may comprise one or more selected from 3-methyl pyrazole, 4-methyl pyridazine, 4,5-dimethyl pyridazine, 4-methyl isoxazole, 4-methyl-5-isoxazole, 4-methyl-5-isoxazolamine, 4-ethyl pyridazine, 4-ethyl-5-methyl pyridazine, 5-methyl-4-pyridazine amine, 4,5-dimethyl isoxazole, methyl pyridazine-4-carboxylate, 4-methyl pyrazole, 4-ethyl isoxazole, 3,4-dimethyl isoxazole and 4-methyl-5-isooxazolol.

The content of the antioxidant may be 0.1 to 10% by weight, for example, 0.1% by weight or more, 0.5% by weight or more, and also for example, 10% by weight or less, 8% by weight or less, 5% by weight or less. The present invention prevents corrosion due to oxidation of copper (Cu) and prevents oxidation of tetramethyl ammonium hydroxide (TMAH) by including the antioxidant in the above content.

Specifically, TMAH is reacted with carbon dioxide (CO₂) in the air to convert into tetramethyl ammonium (TMA) carbonate, and the converted material is in the form of a neutral salt and has no removal ability to the photoresist. The antioxidant of the present invention prevents oxidation of TMAH by inhibiting the formation of hydrogen carbonate (HCO₃−), and as a result, it is possible to increase the number of substrates processed.

According to one embodiment, tetramethyl ammonium hydroxide (TMAH) serves to dissolve the photoresist. The content thereof may be 0.1 to 10% by weight, for example, 0.1% by weight or more, 0.5% by weight or more, and also for example, 10% by weight or less, 8% by weight or less, 6% by weight or less.

According to one embodiment, the organic solvent may be an aprotic polar solvent. Specifically, for example, it may comprise one or more selected from dimethyl sulfoxide (DMSO), ethyl pyrrolidone (NEP), methyl pyrrolidone (NMP), methyl formamide (NMF), ethyl formamide (NEF), diethyl formamide (DEF), dimethyl formamide (DMF), dimethyl acetamide (DMAc), dipropylene glycol monomethyl ether (DPM), diethyl sulfoxide, dipropyl sulfoxide, sulfolane, pyrrolidone, dimethyl propionamide (DMPA), and methyl propionamide (NMPA).

The content of the organic solvent may be 60 to 90% by weight, for example, 60% by weight or more, 70% by weight or more, 80% by weight or more, and also for example, 90% by weight or less, 85% by weight or less.

According to one embodiment, the amine compound may have a molecular weight of 80 to 250 g/mol, for example, 100 to 200 g/mol. If the molecular weight is too low, it may cause corrosion of the metal.

Specifically, for example, the amine compound may comprise one or more selected from tetra ethylene pentamine (TEPA), amino ethoxy ethanol (AEE), mono ethanol amine (MEA), mono isopropanol amine (MIPA), diethylene triamine (DETA), diisopropyl amine (DIPA) and amino ethyl ethanol amine (AEEA).

The content of the amine compound may be 0.1 to 10% by weight, for example, 0.1% by weight or more, 0.5% by weight or more, and also for example, 10% by weight or less, 7% by weight or less, 5% by weight or less.

The present invention can minimize wire resistance-related problems due to not including an inorganic salt. For example, in the semiconductor process, the cations of the inorganic salt such as potassium hydroxide (KOH) remain and affect wire resistance, which may cause defects.

According to one embodiment, the present invention may contain the remaining amount of water such that the total weight of the composition is 100% by weight. The water used is not particularly limited, but deionized water may be used. Preferably, deionized water having a specific resistance value of 18 MΩ/cm or more indicating the degree of removal of ions in the water may be used.

According to one embodiment, in order to improve performance, the composition of the present invention may further comprise any additives commonly used in the art. For example, it may further comprise one or more selected from the group consisting of a stabilizer, a surfactant, a chelating agent, a corrosion inhibitor, an antioxidant, and a mixture thereof.

The stabilizer may be an etch stabilizer and may be included in order to suppress the occurrence of side reactions or byproducts that may be accompanied by unnecessary reactions of the composition or the object to be treated.

The surfactant may be additionally added for the purpose of improving the wettability of the composition, improving the foam properties of the additive, and increasing solubility in organic additive. The surfactant includes one or two or more selected from a nonionic surfactant, an anionic surfactant, a cationic surfactant, and an amphoteric surfactant and may be added in an amount of 0.0005 to 5% by weight based on the total weight of the composition, preferably 0.001 to 2% by weight based on the total weight of the composition. If the content of the surfactant is less than 0.0005% by weight based on the total weight of the composition, no effect can be expected, and when added more than 5% by weight, solubility problems may occur or process problems due to excessive foaming may occur.

The chelating agent may be additionally added for the purpose of increasing the solubility of the composition to metal impurities or forming a uniform etched surface. The chelating agent includes one or two or more selected from organic acids containing a carboxyl group, preferably an organic acid having a carboxyl group and a hydroxyl group simultaneously and may be added in an amount of 0.1 to 5% by weight based on the total weight of the composition.

The corrosion inhibitor and antioxidant may be additionally added to protect metals or metal compounds used as materials for semiconductor devices. The corrosion inhibitor and antioxidant may be used without limitation as long as they are commonly used in the art, for example, it may include an azole-based compound, but is not limited thereto. It may be added in an amount of 0.01 to 10% by weight based on the total weight of the composition.

Hereinafter, embodiments of the present invention will be described in detail so that those of ordinary skill in the art can easily carry out the present invention. However, the present invention may be embodied in several different forms and is not limited to the embodiments described herein.

### EXAMPLES

Each photoresist stripper composition was prepared with a composition according to Table 1. The unit of content is wt %.

TABLE 1

| | Alkaline-based | | | | | | | | |
|---|---|---|---|---|---|---|---|---|---|
| | compound | | Cyclic antioxidant | | Amine compound | | Organic solvent | | Water |
| Composition | Type | Content | Type | Content | Type | Content | Type | Content | Content |
| Example | TMAH | 3 | 4-methyl | 2 | AEE | 2 | DMSO | 80 | Balance |
| 1 | | | pyridazine | | | | | | |
| Example | TMAH | 3 | 4,5-dimethyl | 1 | AEE | 1 | DMSO | 80 | Balance |
| 2 | | | pyridazine | | | | | | |
| Example | TMAH | 4 | 4-methyl | 2 | DETA | 2 | DMSO | 85 | Balance |
| 3 | | | isoxazole | | | | | | |
| Example | TMAH | 2 | 3- | 1 | DETA | 3 | NEP | 85 | Balance |
| 4 | | | methylpyrazole | | | | | | |
| Example | TMAH | 3 | 4-methyl-5- | 3 | DIPA | 3 | NMP | 85 | Balance |
| 5 | | | isoxazole | | | | | | |
| Example | TMAH | 2 | 4-methyl-5- | 3 | DETA | 3 | NMF | 85 | Balance |
| 6 | | | isoxazol | | | | | | |
| | | | amine | | | | | | |
| Example | TMAH | 1 | 4-ethyl | 1 | TEPA | 3 | NEF | 80 | Balance |
| 7 | | | pyridazine | | | | | | |
| Example | TMAH | 2 | 4-ethyl-5- | 2 | TEPA | 2 | DEF | 80 | Balance |
| 8 | | | methyl | | | | | | |
| | | | pyridazine | | | | | | |
| Example | TMAH | 2 | 5-methyl-4- | 1 | DETA | 2 | NMP | 80 | Balance |
| 9 | | | pyridazine | | | | | | |
| | | | amine | | | | | | |
| Example | TMAH | 2 | 4,5-dimethyl | 3 | DETA | 2 | DMF | 80 | Balance |
| 10 | | | isoxazole | | | | | | |
| Example | TMAH | 3 | Methylpyridazine- | 2 | AEEA | 1 | DMSO | 80 | Balance |
| 11 | | | 4- | | | | | | |
| | | | carboxylate | | | | | | |
| Example | TMAH | 3 | 4-methyl | 1 | AEEA | 1 | DMSO | 80 | Balance |
| 12 | | | pyrazole | | | | | | |
| Example | TMAH | 1 | 4-ethyl | 2 | DIPA | 1 | NMP | 85 | Balance |
| 13 | | | isoxazole | | | | | | |
| Example | TMAH | 2 | 3,4-dimethyl | 2 | TEPA | 1 | NMF | 85 | Balance |
| 14 | | | isoxazole | | | | | | |
| Example | TMAH | 2 | 4-methyl-5- | 2 | TEPA | 2 | NEF | 85 | Balance |
| 15 | | | isoxazolol | | | | | | |

TMAH: tetramethyl ammonium hydroxide
AEE: 2-(2-aminoethoxy)ethanol (Molecular weight: 105.1 g/mol)
DETA: diethylene triamine (Molecular weight: 103.2 g/mol)
DIPA: diisopropylamine (Molecular weight: 101.2 g/mol)
TEPA: tetra ethylene pentamine (Molecular weight: 189.3 g/mol)
AEEA: amino ethyl ethanol amine (Molecular weight: 104.2 g/mol)
DMSO: dimethyl sulfoxide
NEP: N-ethyl pyrrolidone
NMP: N-methyl pyrrolidone
NMF: N-methyl formamide
NEF: N-ethyl formamide
DEF: N,N-diethyl formamide
DMF: N,N-dimethyl formamide

### Comparative Examples

Each photoresist stripper composition was prepared with a composition according to Table 2. The unit of content is wt %.

TABLE 2

| | Alkaline-based | | Cyclic | | Amine | | | | |
|---|---|---|---|---|---|---|---|---|---|
| | compound | | antioxidant | | compound | | Organic solvent | | Water |
| Composition | Type | content | Type | Content | Type | Content | Type | Content | Content |
| Comp. | — | — | — | — | — | — | — | — | 100 |
| Example 1 | | | | | | | | | |
| Comp. | TMAH | 3 | — | — | DETA | 4 | NMP | 90 | Balance |
| Example 2 | | | | | | | | | |
| Comp. | TMAH | 3 | tetrazole | 3 | — | — | DMSO | 80 | Balance |
| Example 3 | | | | | | | | | |
| Comp. | TMAH | 3 | 1,2,4- | 3 | DETA | 2 | DMSO | 85 | Balance |
| Example 4 | | | tri azole | | | | | | |
| Comp. | TMAH | 2 | BTA | 3 | MEA | 2 | NMP | 85 | Balance |
| Example 5 | | | | | | | | | |
| Comp. | TMAH | 3 | TT | 3 | MIPA | 2 | NMF | 80 | Balance |
| Example 6 | | | | | | | | | |
| Comp. | KOH | 2 | pyrazine | 3 | TEPA | 2 | DMSO | 80 | Balance |
| Example 7 | | | | | | | | | |

TMAH: tetramethyl ammonium hydroxide
KOH: potassium hydroxide
DETA: diethylene triamine (Molecular weight: 103.2 g/mol)
MEA: mono ethanol amine (Molecular weight: 61.1 g/mol)
MIPA: mono isopropanol amine (Molecular weight: 75.1 g/mol)
TEPA: tetra ethylene pentamine (Molecular weight: 189.3 g/mol)
DMSO: dimethyl sulfoxide
NMP: N-methyl pyrrolidone
NMF: N-methyl formamide
BTA: benzotriazole
TT: tolyltriazole

### Experimental Example 1: Evaluation of Photoresist Stripping Ability

For each composition, a photoresist film was formed to a thickness of about 50 to 60 μm on a copper-plated wafer to evaluate the photoresist stripping performance Then, the wafer was cut to a size of 2 cm×1.5 cm to prepare a specimen for evaluation. The specimen was immersed in each stripper composition at 60° C. for 7 minutes to remove the photoresist. The specimen from which the photoresist was removed was washed with ultrapure water and dried with nitrogen.

Thereafter, it was confirmed whether or not the photoresist was removed from the dried specimen under a microscope and evaluated by the following evaluation criteria. The results are shown in Tables 3 and 4 below.

⊚: 100% of photoresist removed, no residue

∘: at least 80% and less than 100% of photoresist removed, almost no residue

Δ: at least 50% and less than 80% of photoresist removed, significant amount of residue

x: less than 50% of photoresist removed, rather large amount of residue

### Experimental Example 2: Evaluation of Anti-Corrosion Ability to an Underlying Film

For each stripper composition, a copper film was formed to a thickness of about 1000 Å on a silicon wafer in order to evaluate anti-corrosion ability to the copper film. Then, the wafer was cut to a size of 3 cm×2.5 cm to prepare a specimen for evaluation. After measuring the sheet resistance of the specimen, it was immersed in each stripper composition at 60° C. for 10 minutes. Thereafter, the specimen was washed with ultrapure water and dried with nitrogen.

Then, the sheet resistance of the dried specimen (thickness: 1000 Å) was measured (4-point-probe: CMT-SR1000N(Auto contact system), Specifications: Measuring method: contacted by 4-point probe, Measuring range: 1 mohm/sq˜2 Mohm/sq), and the specific resistance value was obtained using the initial thickness value. Then, the thickness value (Å) was calculated by measuring the sheet resistance after evaluation.

Specific resistance (ohm·cm)=ohm/sq×Thickness (cm)

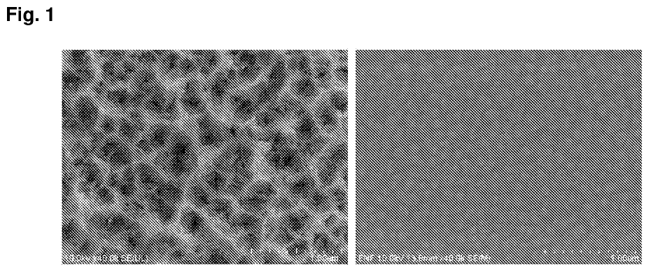

The corrosion degree of the copper film surface was investigated by comparing the etching thickness values before and after the stripping, and evaluated by the following evaluation criteria. The results are shown in Tables 3 and 4 below, and FIG. 1

In FIG. 1, the left side is the result according to Comparative Example 2, and the right side is the result according to Example 1.

No corrosion: 50 Å or less

Minor corrosion: more than 50 Å and 100 Å or less

Corrosion occurrence: more than 100 Å and 500 Å or less

Severe corrosion: more than 500 Å and 1000 Å or less

As shown in the photograph according to the Comparative Example, it was confirmed that the surface of the copper substrate treated with the composition comprising tetramethyl ammonium hydroxide was damaged.

On the other hand, it was confirmed that the surface of the copper substrate treated with the composition of Example was not damaged at all.

### Experimental Example 3: Evaluation of Stability Over Time

The stability of each stripper composition over time was evaluated. In each of Examples and Comparative Examples, the concentration of tetramethyl ammonium hydroxide (TMAH) was checked through acid titration analysis after changing over time under stress condition of heating to 60° C. for 48 hours. Results evaluated by the following evaluation criteria are shown in Tables 3 and 4 below.

⊚: 10% or less of TMAH concentration change rate

∘: more than 10% and 30% or less of TMAH concentration change rate

Δ: more than 30% and 50% or less of TMAH concentration change rate

X: more than 50% and 100% or less of TMAH concentration change rate

TABLE 3

| | Stripping | Anti-corrosion | Stability |
|---|---|---|---|
| Example | ability | ability (Å) | over time |
| Example 1 | ⊚ | 24 | ⊚ |
| Example 2 | ⊚ | 64 | ⊚ |
| Example 3 | ⊚ | 31 | ⊚ |
| Example 4 | ⊚ | 10 | ⊚ |
| Example 5 | ⊚ | 51 | ⊚ |
| Example 6 | ⊚ | 71 | ⊚ |
| Example 7 | ○ | 11 | ⊚ |
| Example 8 | ⊚ | 15 | ⊚ |
| Example 9 | ⊚ | 66 | ⊚ |
| Example 10 | ⊚ | 42 | ○ |
| Example 11 | ⊚ | 34 | ⊚ |
| Example 12 | ⊚ | 12 | ⊚ |
| Example 13 | ⊚ | 31 | ⊚ |
| Example 14 | ⊚ | 53 | ○ |
| Example 15 | ⊚ | 68 | ○ |

TABLE 4

| | Stripping | Anti-corrosion | Stability |
|---|---|---|---|
| Example | ability | ability (Å) | over time |
| Comp. Example 1 | x | 3 | — |
| Comp. Example 2 | ⊚ | 998 | x |
| Comp. Example 3 | x | 990 | x |
| Comp. Example 4 | ⊚ | 748 | x |
| Comp. Example 5 | ⊚ | 998 | x |
| Comp. Example 6 | ⊚ | 893 | x |
| Comp. Example 7 | ○ | 990 | x |

As shown in Tables 3 and 4, all of the compositions according to Examples hardly caused corrosion, and were excellent in both stripping ability and stability over time. In particular, it was confirmed that the composition according to Example 4 had excellent stripping ability and stability over time, as well as most excellent anti-corrosion.

On the other hand, most of the compositions according to Comparative Examples caused severe corrosion. It was confirmed that for the composition according to Comparative Example 1, there was no corrosion, but the stripping ability was lowered and a large amount of photoresist remained, indicating that the composition is not suitable as a photoresist stripper composition.

As described above, the photoresist stripper composition according to the present invention can suppress corrosion of the lower metal film while improving stripping performance and stability over time.

As described above, specific parts of the present invention have been described in detail, and it is clear that these specific descriptions are only preferred embodiments for those of ordinary skill in the art to which the present invention pertains, and the scope of the present invention is not limited thereto. Those of ordinary skill in the art to which the present invention pertains will be able to make various applications and modifications within the scope of the present invention based on the above contents. Accordingly, the substantial scope of the present invention will be defined by the appended claims and their equivalents.

What is claimed is:

1. A composition for photoresist stripper comprising:
an organic solvent;
tetramethyl ammonium hydroxide;
an amine compound; and
an antioxidant,
wherein the composition does not contain an inorganic salt, and
wherein the antioxidant includes a compound of formula 1 or 2: 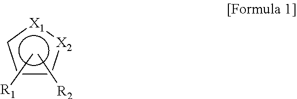
wherein
X₁ and X₂ are each independently N or O,
R₁ and R₂ are each independently H, a C₁₋₂ alkyl group, OH or NH₂, and are not H at the same time, and
when R₁ or R₂ is OH, X₁ or X₂ is O; 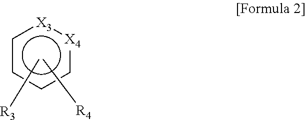
wherein
X₃ and X₄ are each independently N or O, and
R₃ and R₄ are each independently H, a C₁₋₂ alkyl group, COORₐ, OH or NH₂ and Rₐ is H or a C₁₋₂ alkyl group.

2. The composition for photoresist stripper according to claim 1, wherein the antioxidant includes a compound of formula 1 or 2: 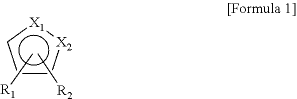
wherein
X₁ and X₂ are each independently N or O,
R₁ and R₂ are each independently H, a C₁₋₂ alkyl group, OH or NH₂, and are not H at the same time,
when R₁ or R₂ is OH, X₁ or X₂ is O, and
when R₁ or R₂ is a C₂ alkyl group, the other R¹ or R₂ is H; 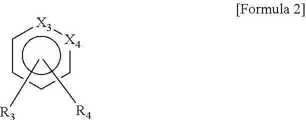
wherein
X₃ and X₄ are N, and
R₃ and R₄ are each independently H, a C₁₋₂ alkyl group, COOH or COOCH₃.

3. The composition for photoresist stripper according to claim 1, wherein the antioxidant comprises one or more selected from 3-methyl pyrazole, 4-methyl pyridazine, 4,5-dimethyl pyridazine, 4-methyl isoxazole, 4-methyl-5-isoxazole, 4-methyl-5-isoxazolamine, 4-ethyl pyridazine, 4-ethyl-5-methyl pyridazine, 5-methyl-4-pyridazine amine, 4,5-dimethyl isoxazole, methyl pyridazine-4-carboxylate, 4-methyl pyrazole, 4-ethyl isoxazole, 3,4-dimethyl isoxazole and 4-methyl-5-isooxazolol.

4. The composition for photoresist stripper according to claim 1, wherein the organic solvent comprises one or more selected from dimethyl sulfoxide, ethyl pyrrolidone, methyl pyrrolidone, methyl formamide, ethyl formamide, diethyl formamide, dimethyl formamide, dimethyl acetamide, dipropylene glycol monomethyl ether, diethyl sulfoxide, dipropyl sulfoxide, sulfolane, pyrrolidone, dimethyl propionamide, and methyl propionamide.

5. The composition for photoresist stripper according to claim 1, wherein the amine compound has a molecular weight of 80 to 250 g/mol.

6. The composition for photoresist stripper according to claim 1, wherein the amine compound comprises one or more selected from tetraethylene pentamine, amino ethoxy ethanol, mono ethanol amine, mono isopropanol amine, diethylene triamine, diisopropyl amine, and amino ethyl ethanol amine.

7. A method for producing a composition for photoresist stripper, comprising adding:
60 to 90% by weight of an organic solvent;
0.1 to 10% by weight of tetramethyl ammonium hydroxide;
0.1 to 10% by weight of an amine compound;
0.1 to 10% by weight of an antioxidant; and
the remaining amount of water so that the total weight of the composition is 100% by weight,
wherein no inorganic salt is added; and
wherein the antioxidant includes a compound of formula 1 or 2: 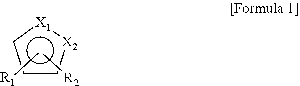
wherein
X₁ and X₂ are each independently N or O,
R₁ and R₂ are each independently H, a C₁₋₂ alkyl group, OH or NH₂, and are not H at the same time, and
when R₁ or R₂ is OH, X₁ or X₂ is O; 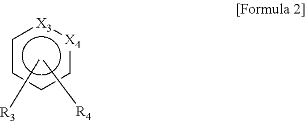
wherein
X₃ and X₄ are each independently N or O, and
R₃ and R₄ are each independently H, a C₁₋₂ alkyl group, COORₐ, OH or NH₂ and Rₐ is H or a C₁₋₂ alkyl group.
